(19) United States
(12) Patent Application Publication
(10) Pub. No.: US 2024/0377747 A1
(43) Pub. Date: Nov. 14, 2024

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventor: Seil CHOI, Suwon-si (KR)

(21) Appl. No.: 18/588,606

(22) Filed: Feb. 27, 2024

(30) Foreign Application Priority Data
May 8, 2023 (KR) 10-2023-0059328

(51) Int. Cl. G03F 7/11; C09D 165/00; H01L 21/027; H01L 21/308; H01L 21/311; H01L 21/3213

(52) U.S. Cl. CPC G03F 7/11; C09D 165/00; H01L 21/0271; H01L 21/308; H01L 21/31144; H01L 21/32139

(57) ABSTRACT

A hardmask composition, including a hardmask layer including a cured product of the hardmask composition, and a method of forming patterns using the hardmask layer including a cured product of the hardmask composition, the hardmask composition including a compound represented by Chemical Formula 1; and a solvent,

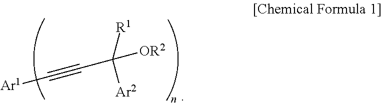

### CROSS-REFERENCE TO RELATED APPLICATION

This application claims priority to and the benefit of Korean Patent Application No. 10-2023-0059328 filed in the Korean Intellectual Property Office on May 8, 2023, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may utilize lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

According to small-sizing the pattern to be formed, it may be difficult to provide a fine pattern having an excellent profile by only using some lithographic techniques. Accordingly, an auxiliary layer, called a hardmask layer, may be formed between the material layer and the photoresist layer to provide a fine pattern.

### SUMMARY

The embodiments may be realized by providing a hardmask composition including a compound represented by Chemical Formula 1; and a solvent:

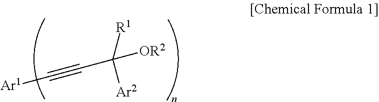

wherein, in Chemical Formula 1, Ar¹ and Ar² are each independently a substituted or unsubstituted C6 to C30 aromatic hydrocarbon group, or a group in which two or more substituted or unsubstituted C6 to C30 aromatic hydrocarbon groups are linked by a single bond or a substituted or unsubstituted C1 to C30 alkylene group,
R¹ and R² are each independently hydrogen, deuterium, a substituted or unsubstituted monovalent C1 to C30 saturated or unsaturated aliphatic hydrocarbon group, a substituted or unsubstituted monovalent C3 to C30 saturated or unsaturated alicyclic hydrocarbon group, a substituted or unsubstituted C6 to C30 aromatic hydrocarbon group, or a combination thereof, and
n is an integer of 2 to 6.

Ar¹ and Ar² of Chemical Formula 1 may each independently be a substituted or unsubstituted group of a moiety of Group 1:

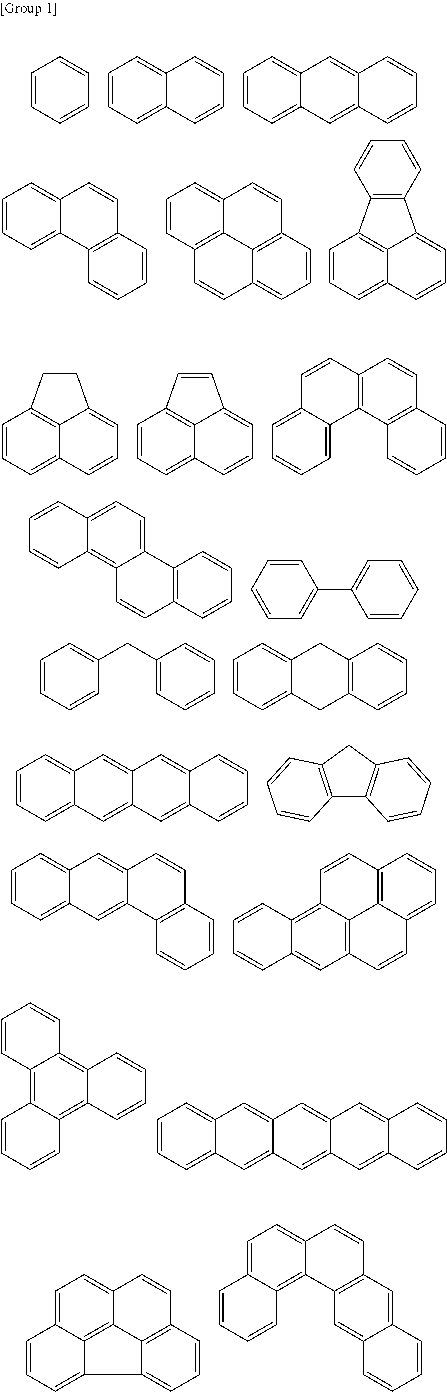

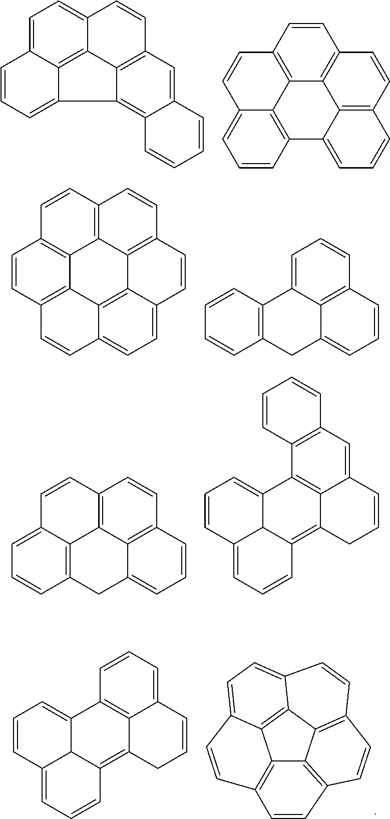

Ar¹ and Ar² in Chemical Formula 1 may each independently be a substituted or unsubstituted group of a moiety of Group 1-1:

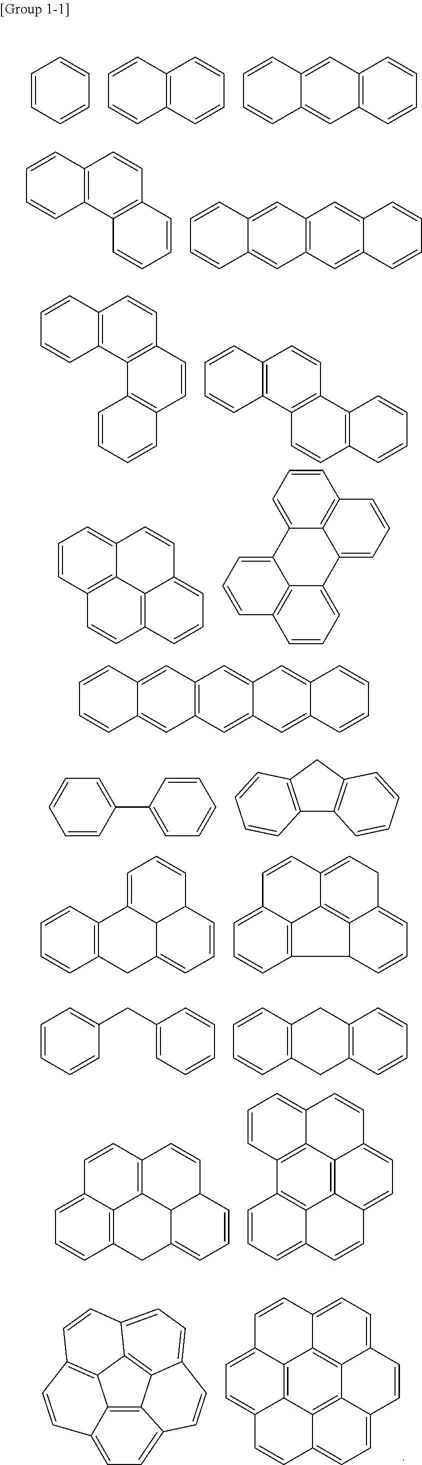

R¹ and R² in Chemical Formula 1 may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aromatic hydrocarbon group, or a combination thereof.

R¹ and R² in Chemical Formula 1 may each independently be hydrogen, deuterium, a substituted or unsubstituted C1 to C10 alkyl group, a substituted or unsubstituted C6 to C20 aromatic hydrocarbon group, or a combination thereof.

Ar¹ and Ar² in Chemical Formula 1 may each independently be a substituted or unsubstituted group of a moiety of Group 1-2, R¹ and R² may each independently be hydrogen, deuterium, a substituted or unsubstituted C1 to C10 alkyl group, a substituted or unsubstituted C6 to C20 aromatic hydrocarbon group, or a combination thereof, and n may be an integer of 2 to 4,

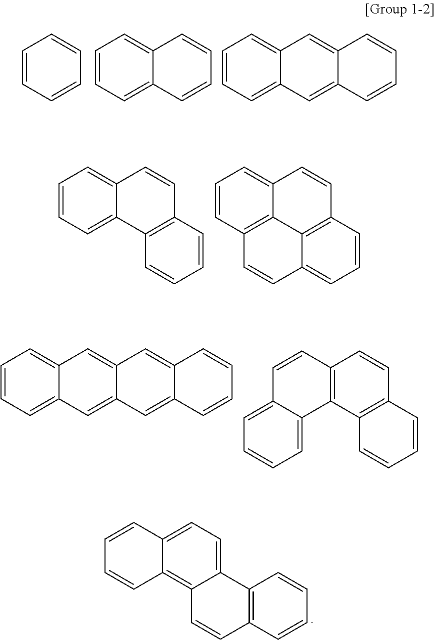

In Chemical Formula 1, n may be 2 or 3, and R¹, R², and Ar² may be the same.

The compound represented by Chemical Formula 1 may be represented by one of Chemical Formula 2 to Chemical Formula 10:

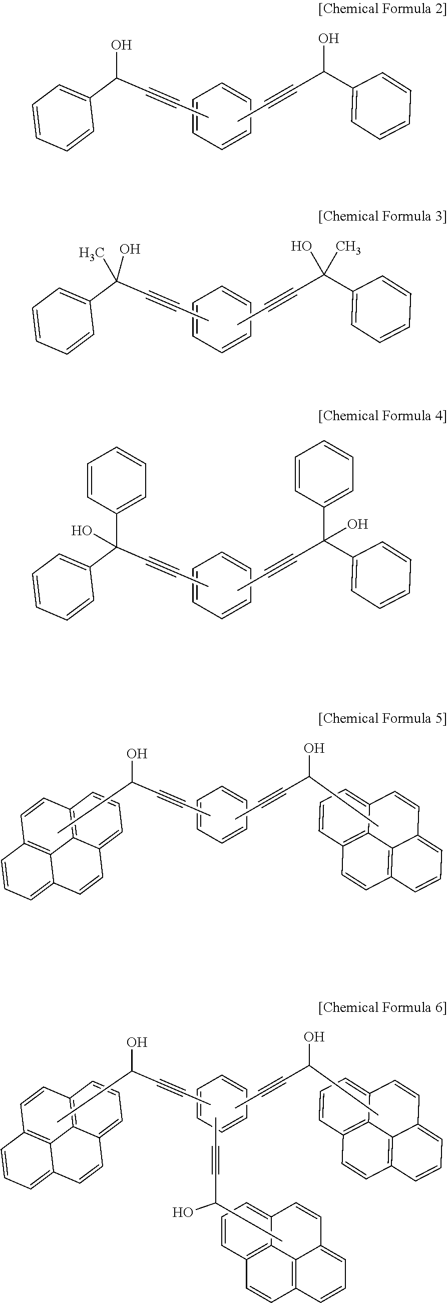

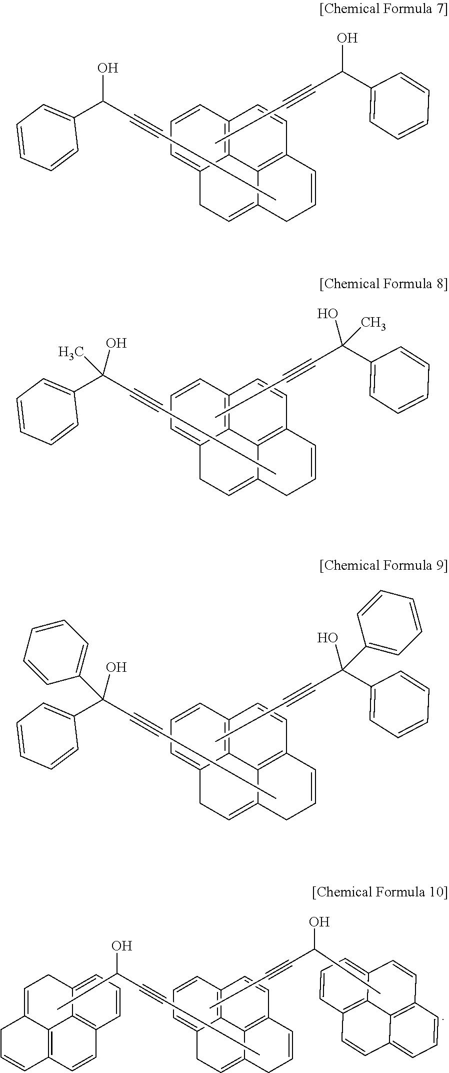

The compound may have a molecular weight of about 300 g/mol to about 10,000 g/mol.

The compound may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer including a cured product of the hardmask composition according to an embodiment.

According to some embodiments, a method of forming patterns may include providing a material layer on a substrate; applying the hardmask composition according to an embodiment to the material layer to form a hardmask layer; heat-treating the hardmask composition to form a hardmask layer; forming a photoresist layer on the hardmask layer; exposing and developing the photoresist layer to form a photoresist pattern, selectively removing the hardmask layer using the photoresist pattern to expose a portion of the material layer; and etching an exposed part of the material layer.

Forming the hardmask layer may include heat-treating at about 100° C. to about 1,000° C.

### BRIEF DESCRIPTION OF THE DRAWING

Features will become apparent to those of skill in the art by describing in detail exemplary embodiments with reference to the attached drawing in which:

the FIGURE shows a reference diagram illustrating a level difference of a hardmask layer to explain a method of evaluating planarization characteristics and a calculation formula for evaluating planarization characteristics.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (-D) or tritium substitution (-T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B. As used herein, unless described otherwise, * is a linking point.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aromatic hydrocarbon group” refers to a group having one or more hydrocarbon aromatic moieties, including a form in which hydrocarbon aromatic moieties are linked by a single bond, a non-aromatic fused ring form in which hydrocarbon aromatic moieties are fused directly or indirectly, or a combination thereof as well as non-fused aromatic hydrocarbon rings, fused aromatic hydrocarbon rings.

More specifically, a substituted or unsubstituted aromatic hydrocarbon group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups, but is not limited thereto.

Unless otherwise specified in the present specification, the “molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may include a compound represented by Chemical Formula 1, and a solvent.

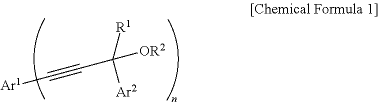

In Chemical Formula 1, Ar¹ and Ar² may each independently be or include, e.g., a substituted or unsubstituted C6 to C30 aromatic hydrocarbon group, or a group in which two or more substituted or unsubstituted C6 to C30 aromatic hydrocarbon groups may be linked by a single bond or a substituted or unsubstituted C1 to C30 alkylene group.

R¹ and R² may each independently be or include, e.g., hydrogen, deuterium, a substituted or unsubstituted monovalent C1 to C30 saturated or unsaturated aliphatic hydrocarbon group, a substituted or unsubstituted monovalent C3 to C30 saturated or unsaturated alicyclic hydrocarbon group, a substituted or unsubstituted C6 to C30 aromatic hydrocarbon group, or a combination thereof.

n may be an integer of 2 to 6.

The compound according to some embodiments may include an aromatic hydrocarbon group as shown in Chemical Formula 1 and at the same time may have a triple bond directly linked to the central aromatic hydrocarbon ring, thereby increasing the carbon content in the composition and improving crosslinking characteristics if curing a hardmask composition including the compound according to some embodiments.

Chemical Formula 1 may include a substituent represented by —OR², so that solubility of the compound in a solvent may be improved, and a hardmask composition including it may be effectively applied to a spin-on coating process. In addition, since the compound may be crosslinked into a high molecular weight polymer form within a short period of time upon heat treatment, the hardmask layer formed therefrom may have excellent heat resistance and excellent etch resistance.

Ar¹ and Ar² in Chemical Formula 1 may each independently be a substituted or unsubstituted group of a moiety of Group 1.

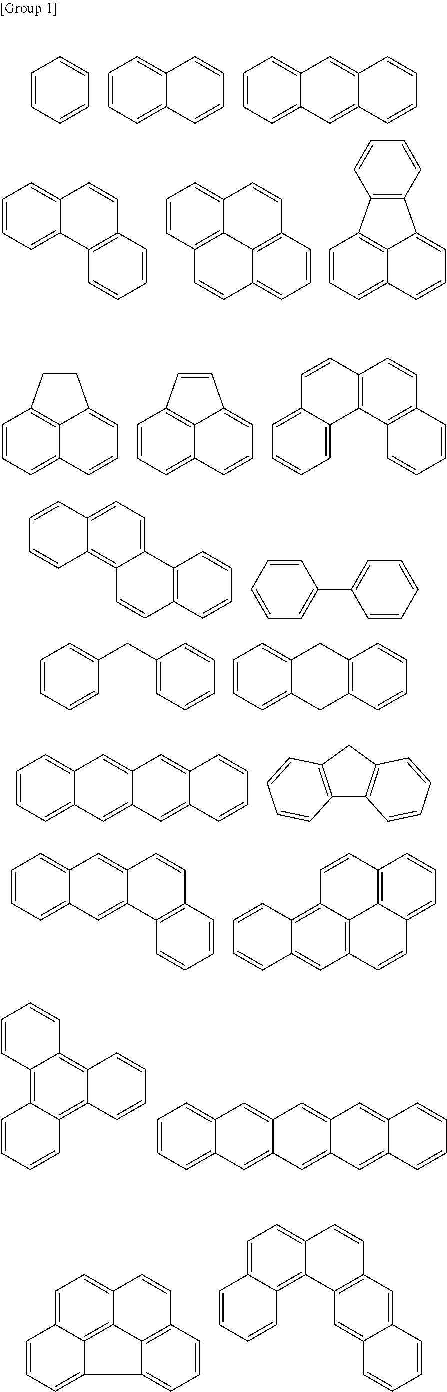

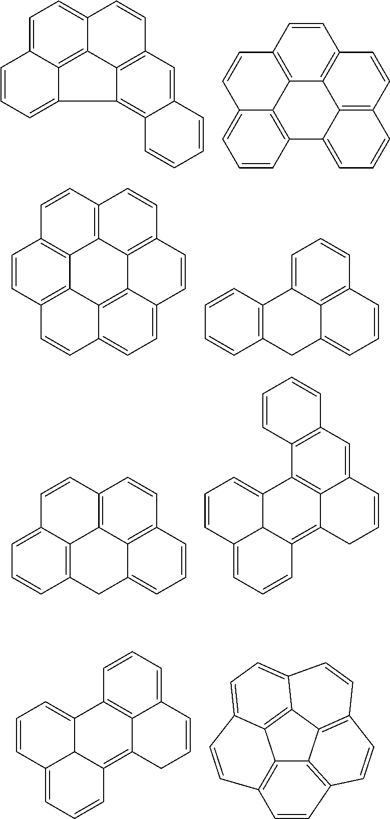

In an implementation, Ar¹ and Ar² in Chemical Formula 1 may each independently be a substituted or unsubstituted group of a moiety of Group 1-1.

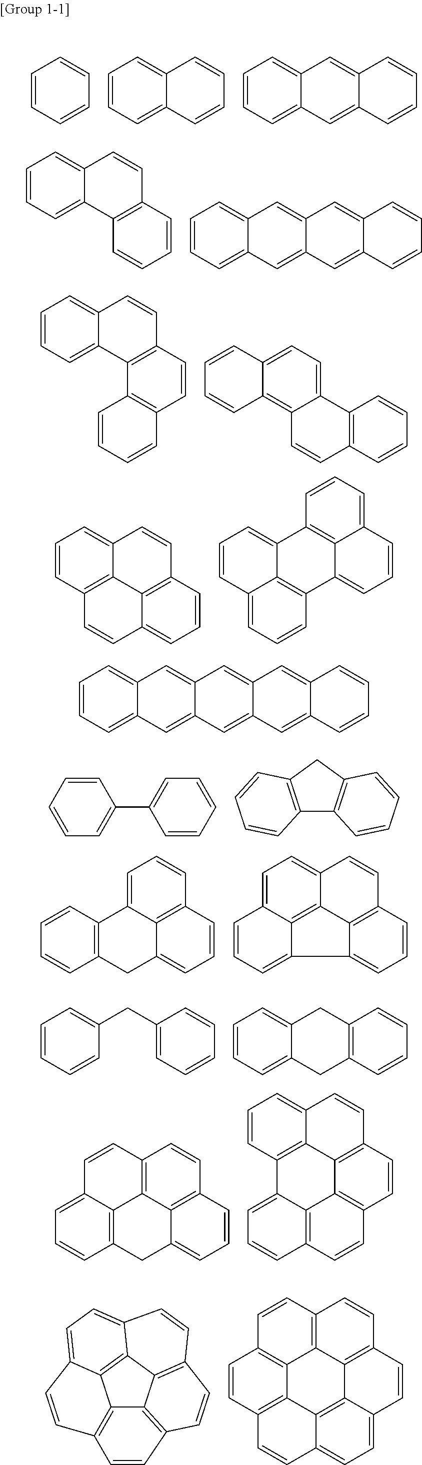

In an implementation, Ar¹ and Ar² in Chemical Formula 1 may each independently be a substituted or unsubstituted group of a moiety of Group 1-2.

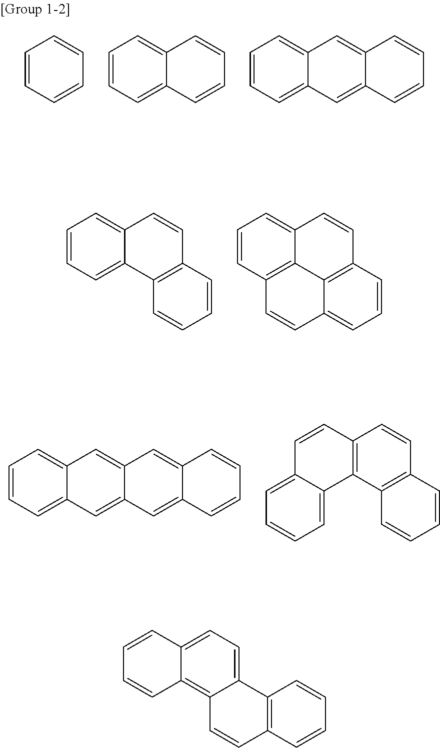

R¹ and R² in Chemical Formula 1 may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aromatic hydrocarbon group, or a combination thereof. In an implementation, R¹ and R² in Chemical Formula 1 may each independently be hydrogen, deuterium, a substituted or unsubstituted C1 to C10 alkyl group, a substituted or unsubstituted C6 to C20 aromatic hydrocarbon group, or a combination thereof. In an implementation, R¹ and R² in Chemical Formula 1 may be hydrogen, a methyl group, an ethyl group, a propyl group, a butyl group, a phenyl group, a naphthyl group, a phenanthryl group, an anthryl group, or a pyrenyl group, e.g., hydrogen, a methyl group, or a phenyl group.

In an implementation, in the compound represented by Chemical Formula 1, Ar¹ and Ar² may each independently be a substituted or unsubstituted group of a moiety of Group 1-2, R¹ and R² may each independently be hydrogen, deuterium, a substituted or unsubstituted C1 to C10 alkyl group, a substituted or unsubstituted C6 to C20 aromatic hydrocarbon group, or a combination thereof, and n may be an integer of 2 to 4.

In an implementation, in Chemical Formula 1, n may be an integer of 2 to 6. In an implementation, n may be an integer of 2 to 4, e.g., n may be 2 or 3. In an implementation, if n in Chemical Formula 1 is 2 or 3, solubility of the compound according to some embodiments in the solvent may be optimized and the etch resistance of the hardmask layer formed from the hardmask composition containing the compound may be maximized.

In an implementation, if n in Chemical Formula 1 is 2 or 3, each of R¹, R², and Ar² may be the same or different from each other. In an implementation, if n is 2 or 3, each of the two or three R's may be the same as or different from each other, each of the two or three R²s may be the same as or different from each other, and each of the two or three Ar²s may be the same as or different from each other.

In an implementation, the compound represented by Chemical Formula 1 may be represented by one of Chemical Formula 2 to Chemical Formula 10.

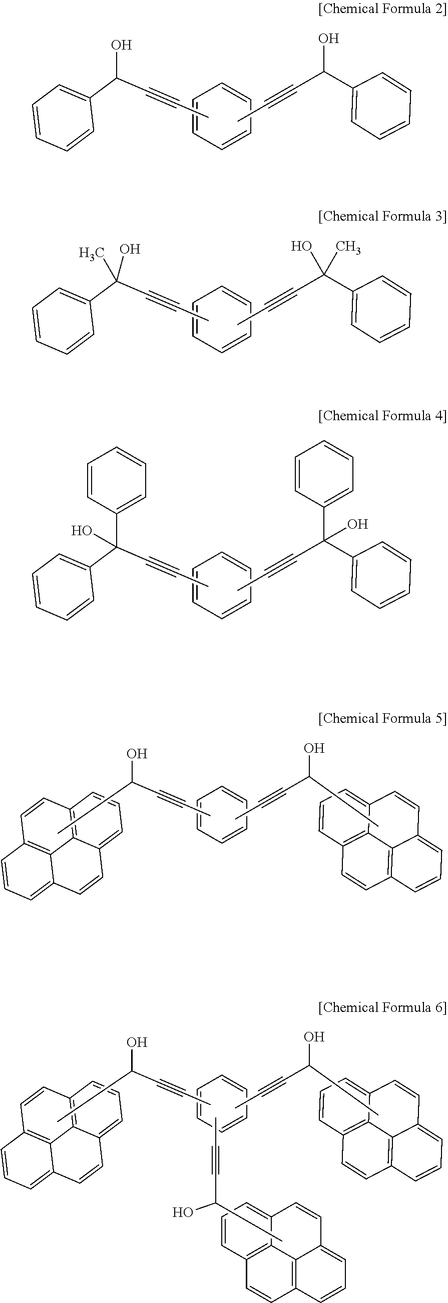

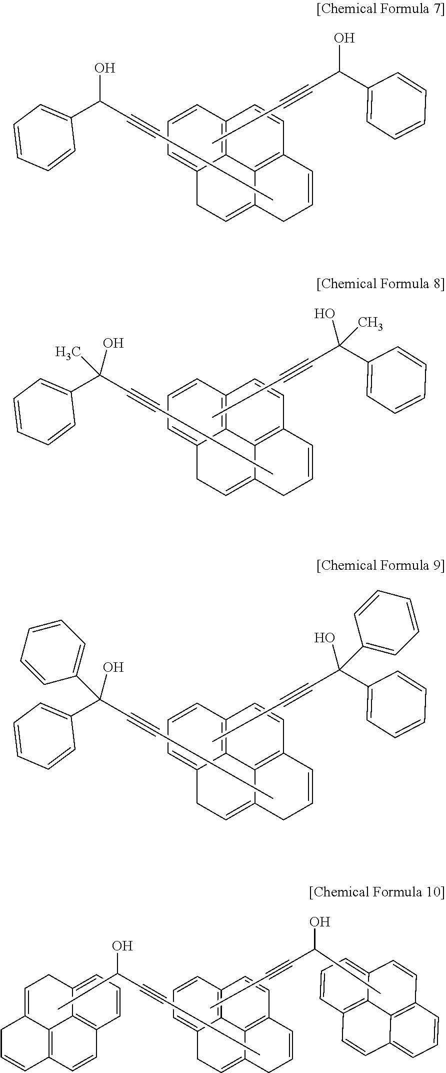

The compound may have a molecular weight of, e.g., about 300 g/mol to about 10,000 g/mol. In an implementation, the compound may have a molecular weight of about 400 g/mol to about 10,000 g/mol, e.g., about 500 g/mol to about 10,000 g/mol, about 500 g/mol to about 9,500 g/mol, about 500 g/mol to about 9,000 g/mol, about 600 g/mol to about 8,500 g/mol, about 600 g/mol to about 8,000 g/mol, about 700 g/mol to about 7,500 g/mol, or about 700 g/mol to about 7,000 g/mol. By having a molecular weight within the above ranges, the carbon content and solubility in the solvent of the hardmask composition including the above compound may be adjusted and optimized.

The compound may be included in an amount of, e.g., about 0.1 wt % to about 30 wt % based on a total weight of the hardmask composition. In an implementation, the compound may be included in an amount of, e.g., about 0.2 wt % to about 30 wt %, about 0.5 wt % to about 30 wt %, about 1 wt % to about 30 wt %, about 1 wt % to about 25 wt %, or about 1 wt % to about 20 wt %. By including the compound within the above ranges, a thickness, a surface roughness, and a planarization degree of the hardmask may be easily adjusted.

The hardmask composition may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. In an implementation, the solvent may be a suitable solvent that has sufficient solubility or dispersibility for the compound.

In an implementation, the hardmask composition may further include an additive, e.g., a surfactant, a crosslinking agent, a thermal acid generator, or a plasticizer.

The surfactant may include, e.g., a fluoroalkyl-based compound, alkylbenzenesulfonate, alkylpyridinium salt, polyethylene glycol, a quaternary ammonium salt, and the like.

The crosslinking agent may be, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

In an implementation, the thermal acid generator may be, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid or 2,4,4,6-tetrabromocyclohexadienone, benzointosylate, 2-nitrobenzyltosylate, or other organic sulfonic acid alkyl esters.

According to some embodiments, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned compound and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer may be a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1,000° C. for about 10 seconds to about 1 hour, and, e.g., the heat-treating may be performed under an atmosphere of air or nitrogen, or an atmosphere having oxygen concentration of 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, e.g., about 30 seconds to about 30 minutes, about 30 seconds to about 10 minutes, or about 30 seconds to about 5 minutes.

In an implementation, the heat-treating of the hardmask composition may include, e.g., a second heat-treating process performed at about 100° C. to 1,000° C., about 300° C. to about 1,000° C., about 500° C. to about 1,000° C., or about 500° C. to about 600° C. for about 30 seconds to about 1 hour, e.g., about 30 seconds to about 30 minutes, about 30 seconds to about 10 minutes, about 30 seconds to about 5 minutes, consecutively. In an implementation, the first and second heat-treating process may be performed under an air or nitrogen atmosphere, or may be performed under an atmosphere with an oxygen concentration of 1 wt % or less.

By performing at least one of the steps of heat-treating the hardmask composition at a high temperature, e.g., of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may include, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may be, e.g., N₂/O₂, CHF₃, CF₄, Cl₂, BCl₃, or a mixed gas thereof.

The etched material layer may be formed in a plurality of patterns, and the plurality of patterns may be a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Compounds

### Synthesis Example 1

24.7 g of potassium tert-butoxide was added to a mixed solution cooled under a nitrogen atmosphere of 12.6 g of 1,3-diethynylbenzene, 21.2 g of benzaldehyde, and 200 g of tetrahydrofuran (THF) and then, stirred, until the 1,3-diethynylbenzene was all reacted. After the stirring, water was added thereto to stop the reaction. Subsequently, 200 g of tetrahydrofuran (THF) was added thereto and then, washed and concentrated under a reduced pressure, and a solid generated therein was filtered with n-hexane and dried under the reduced pressure to obtain Compound A represented by Chemical Formula 2-1.

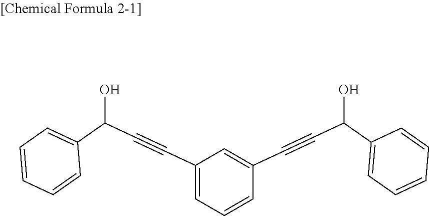 [SMILES: OC(C#Cc1cccc(C#CC(O)c2ccccc2)c1)c1ccccc1]

### Synthesis Example 2

Compound B represented by Chemical Formula 3-1 was obtained in the same manner as in Synthesis Example 1 except that 24.0 g of acetophenone was used instead of 21.2 g of the benzaldehyde.

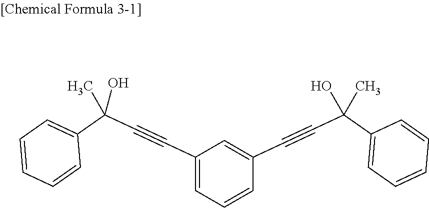 [SMILES: CC(O)(C#Cc1cccc(C#CC(C)(O)c2ccccc2)c1)c1ccccc1]

### Synthesis Example 3

Compound C represented by Chemical Formula 4-1 was obtained in the same manner as in Synthesis Example 1 except that 37.6 g of benzophenone was used instead of 21.2 g of the benzaldehyde.

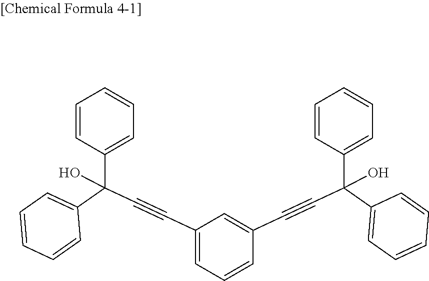 [SMILES: OC(C#Cc1cccc(C#CC(O)(c2ccccc2)c2ccccc2)c1)(c1ccccc1)c1ccccc1]

### Synthesis Example 4

Compound D represented by Chemical Formula 5-1 was obtained in the same manner as in Synthesis Example 1 except that 46.0 g of pyrene carboxaldehyde was used instead of 21.2 g of the benzaldehyde.

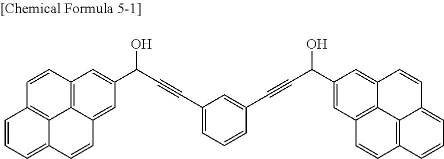 [SMILES: OC(C#Cc1cccc(C#CC(O)c2cc3ccc4cccc5ccc(c2)c3c45)c1)c1cc2ccc3cccc4ccc(c1)c2c34]

### Synthesis Example 5

31.1 g of potassium tert-butoxide was added to a mixed solution cooled under a nitrogen atmosphere of 12.6 g of 1,3,5-triethynylbenzene, 58.0 g of pyrene carboxaldehyde, and 600 g of tetrahydrofuran (THF) and then, stirred in an ice bath, until the 1,3,5-triethynylbenzene was all reacted. After the stirring, water was added to stop the reaction. 600 g of tetrahydrofuran (THF) was added thereto and then, washed and concentrated under a reduced pressure, and a solid generated therefrom was filtered with n-hexane and dried under the reduced pressure to obtain Compound E represented by Chemical Formula 6-1.

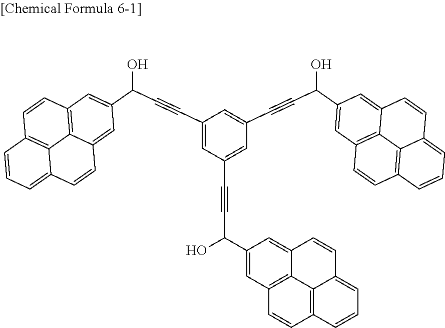 [SMILES: OC(C#Cc1cc(C#CC(O)c2cc3ccc4cccc5ccc(c2)c3c45)cc(C#CC(O)c2cc3ccc4cccc5ccc(c2)c3c45)c1)c1cc2ccc3cccc4ccc(c1)c2c34]

### Synthesis Example 6

18.6 g of potassium tert-butoxide was added to a mixed solution cooled under a nitrogen atmosphere of 12.6 g of diethynylpyrene, 21.2 g of benzaldehyde, and 240 g of tetrahydrofuran (THF) and then, stirred in an ice bath, until the diethynylpyrene was all reacted. After the stirring, water was added thereto to stop the reaction. 240 g of tetrahydrofuran (THF) was added thereto and then, washed and concentrated under a reduced pressure, and a solid generated therein was filtered with n-hexane and dried under the reduced pressure to obtain Compound F represented by Chemical Formula 7-1.

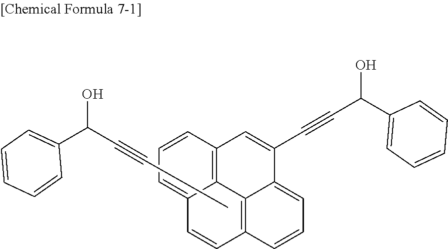

### Synthesis Example 7

Compound G represented by Chemical Formula 8-1 was obtained in the same manner as in Synthesis Example 6 except that 12.1 g of acetophenone was used instead of 21.2 g of the benzaldehyde.

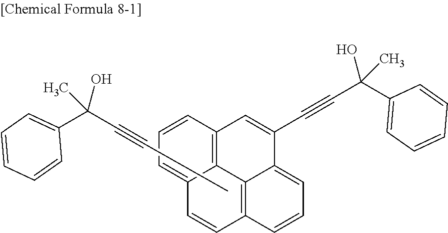

### Synthesis Example 8

Compound H represented by Chemical Formula 9-1 was obtained in the same manner as in Synthesis Example 6 except that 18.6 g of benzophenone was used instead of 21.2 g of the benzaldehyde.

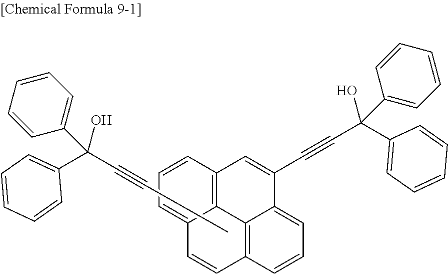

### Synthesis Example 9

Compound I represented by Chemical Formula 10-1 was obtained in the same manner as in Synthesis Example 6 except that 23.2 g of pyrene carboxaldehyde was used instead of 21.2 g of the benzaldehyde.

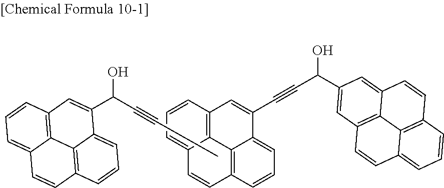

### Comparative Synthesis Example 1

Terephthalaldehyde (13.4 g, 0.1 mol) was dissolved in tetrahydrofuran (THF, 300 ml) and then, cooled to 0° C. under a nitrogen atmosphere. Subsequently, a THF mixed solution in which ethynylmagnesium bromide was dissolved (0.5 M, 30 ml) was slowly added thereto in a dropwise fashion for 1 hour to conduct a reaction. After increasing a temperature thereof to ambient temperature and further performing the reaction for 12 hours, while stirring, the resultant was quenched with a saturated chloride ammonium aqueous solution (saturated NH₄Cl(aq)). When the reaction was completed, the mixed solution was separated (worked-up) with ethyl acetate into an aqueous solution layer and an organic layer, and the organic layer was obtained after removing the aqueous solution layer. A compound represented by Chemical Formula 12-1 was obtained by removing the solvent of the separated organic layer. (Yield: 90%)

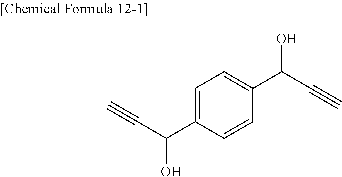

The compound represented by Chemical Formula 12-1 (5.3 g, 0.09 mol) was dissolved in propylene glycol monomethyl ether acetate (PGMEA, 200 ml), and hydroxypyrene (HO-Pyrene, 43 g, 0.2 mol) was added thereto. The mixed solution was heated to 90° C., until the compound represented by Chemical Formula 12-1 was not left. After the reaction, Compound J represented by Chemical Formula 12 was obtained through purification.

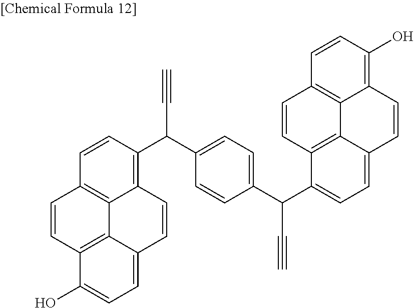 [SMILES: C#CC(c1ccc(C(C#C)c2ccc3ccc4c(O)ccc5ccc2c3c54)cc1)c1ccc2ccc3c(O)ccc4ccc1c2c43]

### Comparative Synthesis Example 2

27.6 g (0.1 mol) of benzoperylene and 42 g (0.22 mol) of naphthoyl chloride was put with 500 g of a mixed solution of chloroform/dichloromethane in a 2 L 3-necked flask and then, reacted by adding 61.2 g (0.35 mol) of aluminum chloride little by little thereto, while stirring by using a stirring bar. When the reaction was completed, water was used to remove trichloroaluminum. A product obtained as powder was dissolved in tetrahydrafuran and then, reacted, while 18.98 g (0.5 mol) of lithium aluminum hydride was little by little added thereto. When the reaction was completed, a by-product of the reaction was removed by using a mixture of water/methanol to obtain Comparative Compound K represented by Chemical Formula 13.

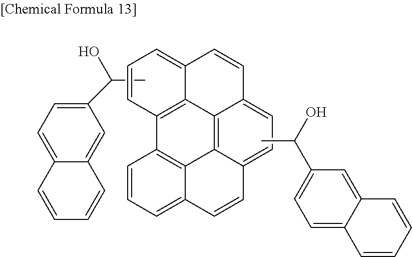

### Preparation of Hardmask Composition

### Example and Comparative Example

Compounds A to I and Comparative Compounds J and K according to Synthesis Examples 1 to 9 and Comparative Synthesis Examples 1 to 2 were respectively dissolved in cyclohexanone and then, filtered to prepare a hardmask composition having a compound content of 10.0 wt %.

### Evaluation 1: Heat Resistance

Each of the hardmask compositions of Examples 1 to 9 and Comparative Examples 1 to 2 was spin-coated on a silicon wafer and heat-treated on a hot plate at 160° C. for 1 minute to form a hardmask layer. A thickness of the hardmask layer was measured by using a film thickness meter made by K-MAC Co., Ltd. Subsequently, the hardmask layer was heat-treated again at 400° C. for 2 minutes and then, measured again with respect to a thickness. After calculating a thickness variation ratio of the two thicknesses before and after the reheat-treatment at 400° C. for 2 minutes, when the ratio was less than 5% before and after the reheat-treatment at 400° C. for 2 minutes, “A” (very good) was given, when greater than or equal to 5% and less than 10%, “B” (good) was given, and when greater than or equal to 10%, “C” (inferior) was given. The results are shown in Table 1.

TABLE 1

| | Heat resistance |
|---|---|
| Example 1 | A |
| Example 2 | A |
| Example 3 | A |
| Example 4 | A |
| Example 5 | A |
| Example 6 | A |
| Example 7 | A |
| Example 8 | A |
| Example 9 | A |
| Comparative Example 1 | B |
| Comparative Example 2 | C |

Referring to Table 1, the hardmask layers formed of the compositions of Examples 1 to 9 exhibited a thickness variation ratio of less than 5% before and after the reheat-treatment, and the hardmask layers formed of the compositions of the Comparative Examples exhibited a thickness variation ratio of greater than or equal to 5% before and after the reheat-treatment. In other words, the hardmask layers formed of the compositions of the examples exhibited excellent heat resistance, compared with the hardmask layers formed of the compositions of the Comparative Examples.

### Evaluation 2: Gap-Fill Characteristics

The hardmask compositions of Examples 1 to 9 and Comparative Examples 1 to 2 were respectively spin-coated on a patterned silicon wafer and heat-treated at 400° C. for 60 seconds to form a hardmask layer. Each pattern cross-section image of the hardmask layers was examined by using a field emission-scanning electron microscope (FE-SEM) to check whether voids were generated or not. The results are shown in Table 2.

TABLE 2

| | Whether voids occurred or not |
|---|---|
| Example 1 | Voids did not occur |
| Example 2 | Voids did not occur |
| Example 3 | Voids did not occur |
| Example 4 | Voids did not occur |
| Example 5 | Voids did not occur |
| Example 6 | Voids did not occur |
| Example 7 | Voids did not occur |
| Example 8 | Voids did not occur |
| Example 9 | Voids did not occur |
| Comparative Example 1 | Voids did occur |
| Comparative Example 2 | Voids did not occur |

Referring to Table 2, in the hardmask layers formed of the compositions according to Examples 1 to 9, voids were not generated, but in the hardmask layer formed of the composition according to Comparative Example 1, the voids were found. Accordingly, the hardmask layers formed of the compositions according to the examples exhibited equivalent or excellent gap-fill characteristics, compared with the hardmask layer formed of the composition according to the Comparative Example.

### Evaluation 3: Planarization Characteristics

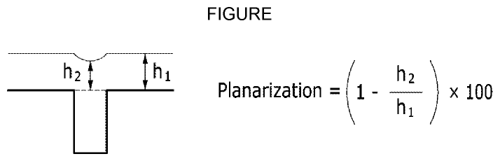

Each of the hardmask compositions according to Examples 1 to 9 and Comparative Examples 1 to 3 was spin-coated on a patterned silicon wafer and heat-treated at 400° C. for 60 seconds, and a pattern cross-section image thereof was examined by using a field emission-scanning electron microscope (FE-SEM). A hardmask layer on the pattern cross-section image was measured with respect to a thickness, and planarization degrees thereof was digitized according to Calculation Equation of FIG. 1. In the FIGURE, h₁ was obtained by measuring each thickness at three random points in an unpatterned region of the hardmask layer and calculating an average thereof, and h₂ was obtained by measuring each thickness at three random points in a patterned region of the hardmask layer and calculating an average thereof. If the numerical results of planarization degrees were less than 5, “A” (very good) was given, if they were between 5 and 10, “B” (good) were given, and if they were over 10, “C” (inferior) was given. The results are shown in Table 3.

TABLE 3

| | Planarization characteristics |
|---|---|
| Example 1 | A |
| Example 2 | A |
| Example 3 | A |
| Example 4 | A |
| Example 5 | A |
| Example 6 | A |
| Example 7 | A |
| Example 8 | A |
| Example 9 | A |
| Comparative Example 1 | B |
| Comparative Example 2 | C |

Referring to Table 3, the hardmask layers formed of the hardmask compositions of Comparative Examples 1 to 2 exhibited good or inferior planarization degrees, but the hardmask layers formed of the hardmask compositions of Examples 1 to 9 exhibited very good planarization degrees and thus very excellent planarization characteristics.

### Evaluation 4: Etch Resistance

Each of the hardmask compositions of Examples 1 to 9 and Comparative Examples 1 to 2 was spin-coated on a silicon wafer and heat-treated on a hot plate at 160° C. for 1 minute to form a hardmask layer. The hardmask layer was dry-etched by using CF₄/Ar mixed gas for 30 seconds and then, measured with respect to each thickness before and after the dry etching by using a thin film thickness meter made by K-MAC Co., Ltd., and then, a bulk etch rate (BER) was calculated according to Calculation Equation 2. A ratio of each etch rate of the hardmask layers of the compositions of Examples 1 to 9 and Comparative Example 2 to that of the hardmask layer of the composition of Comparative Example 1 was calculated to evaluate etch resistance. Specifically, when the etch rate was less than 0.95, “A” (very good) was given, when greater than or equal to 0.95 and less than 1.00, “B” (good) was given, and when greater than or equal to 1.00, “C” (inferior) was given. The results are shown in Table 4.

$$Etch rate ( Å / s ) = ( initial thin film thickness - thin film thickness after etching ) \text{} / etching time ( s ) \qquad [ Calculation Equation 2 ]$$

TABLE 4

| | Etch Resistance |
|---|---|
| Example 1 | A |
| Example 2 | A |
| Example 3 | A |
| Example 4 | A |
| Example 5 | A |
| Example 6 | A |
| Example 7 | A |
| Example 8 | A |
| Example 9 | A |
| Comparative Example 1 | — |
| Comparative Example 2 | C |

Referring to Table 4, since each etch rate of the hardmask layers of the compositions of Examples 1 to 9 to that of the hardmask layer formed of the composition of Comparative Example 1 exhibited a ratio of less than 0.95, the hardmask layers of the compositions of Examples 1 to 9 exhibited excellent etch resistance, compared to the hardmask layer formed of the composition of the Comparative Example.

By way of summation and review, there is a constant trend in a semiconductor industry to reduce a size of chips. To respond to this, the line width of the photoresist pattern in lithography technology may have a size of tens of nanometers. Therefore, a height that can withstand the line width of the photoresist pattern may be limited, and there are cases where the photoresists may not have sufficient resistance in the etching step. In order to compensate for this, an auxiliary layer, which is called a hardmask layer, may be used between a material layer to be etched and a photoresist layer. This hardmask layer may serve as an interlayer that transfers a fine pattern of the photoresist through selective etching. Therefore, the hardmask layer may be required to have sufficient etch resistance as to withstand the etching process during the pattern transfer.

Some hardmask layers may be formed in a chemical or physical deposition method and may have low economic efficiency due to a large-scale equipment and a high process cost. Accordingly, a spin-coating technique for forming a hardmask layer has recently been developed. The spin-coating technique may be an easier process to conduct than the conventional method, and a hardmask layer formed therefrom may exhibit much more excellent gap-fill characteristics and planarization characteristics. However, the hardmask layer formed using the spin-coating technique may have a required etch resistance is somewhat lowered. Accordingly, a hardmask composition may be required to apply to the spin-coating technique and to secure equivalent etch resistance to that of the hardmask layer formed in the chemical or physical deposit method.

In order to improve the etch resistance of a hardmask layer, research on maximizing a carbon content of the hardmask composition is being made. As a carbon content of a polymer included in the hardmask composition is maximized, solubility of the polymer in a solvent may decrease. A carbon content of the polymer included in the hardmask composition may be maximized to improve the etch resistance of the hardmask layer formed therefrom, while the polymer may be well soluble in the solvent.

The hardmask composition according to some embodiments may include a compound having an aromatic hydrocarbon group to increase the carbon content in the composition. Accordingly, the hardmask layer obtained from the composition may secure excellent etch resistance. Additionally, by containing specific functional groups, the compound may increase the carbon content in the composition and ensure excellent solubility in solvents.

One or more embodiments may provide a hardmask composition that can be effectively applied to a hardmask layer.

One or more embodiments may provide a hardmask layer including a cured product of the hardmask composition.

One or more embodiments may provide a method of forming patterns using the hardmask composition.

The hardmask composition according to some embodiments may have excellent solubility in solvents and may be effectively applied to a hardmask layer.

The hardmask composition according to some embodiments may have excellent crosslinking characteristics when cured, and the hardmask layer formed therefrom may help secure excellent heat resistance and excellent etch resistance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a compound represented by Chemical Formula 1; and
a solvent, 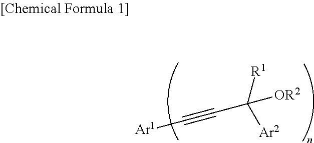
wherein, in Chemical Formula 1,
Ar¹ and Ar² are each independently a substituted or unsubstituted C6 to C30 aromatic hydrocarbon group, or a group in which two or more substituted or unsubstituted C6 to C30 aromatic hydrocarbon groups are linked by a single bond or a substituted or unsubstituted C1 to C30 alkylene group,
R¹ and R² are each independently hydrogen, deuterium, a substituted or unsubstituted monovalent C1 to C30 saturated or unsaturated aliphatic hydrocarbon group, a substituted or unsubstituted monovalent C3 to C30 saturated or unsaturated alicyclic hydrocarbon group, a substituted or unsubstituted C6 to C30 aromatic hydrocarbon group, or a combination thereof, and
n is an integer of 2 to 6.

2. The hardmask composition as claimed in claim 1, wherein Ar¹ and Ar² in Chemical Formula 1 are each independently a substituted or unsubstituted group of a moiety of Group 1:

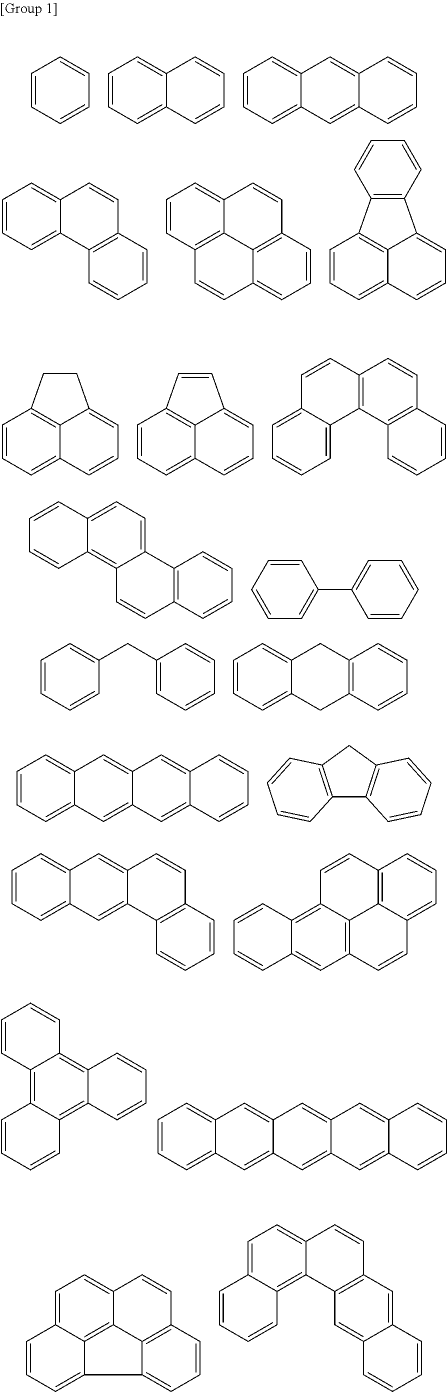

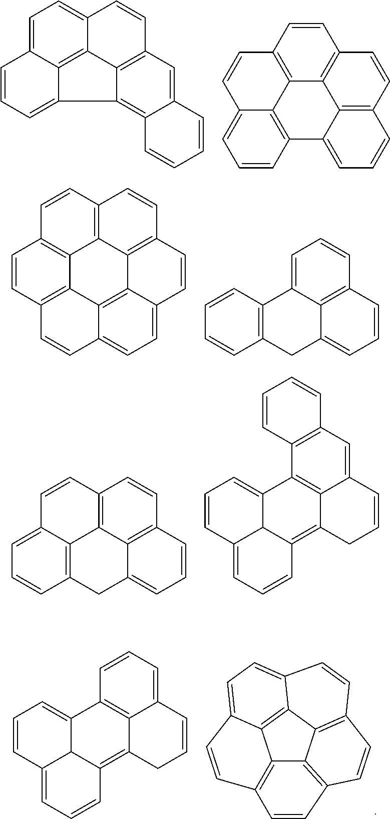

3. The hardmask composition as claimed in claim 1, wherein Ar¹ and Ar² in Chemical Formula 1 are each independently a substituted or unsubstituted group of a moiety of Group 1-1:

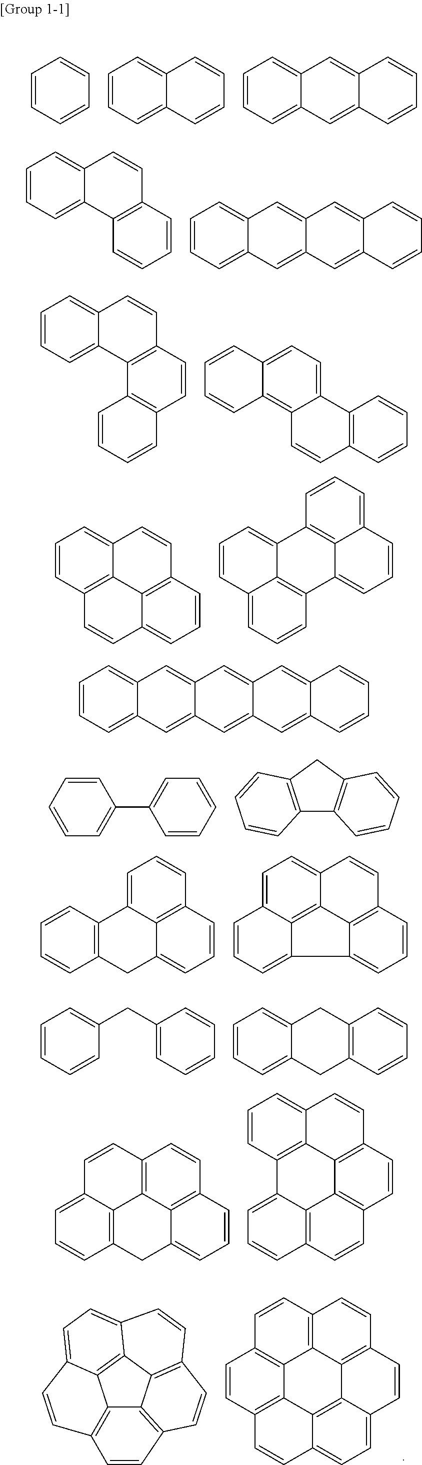

4. The hardmask composition as claimed in claim 1, wherein R¹ and R² in Chemical Formula 1 are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aromatic hydrocarbon group, or a combination thereof.

5. The hardmask composition as claimed in claim 1, wherein R¹ and R² in Chemical Formula 1 are each independently hydrogen, deuterium, a substituted or unsubstituted C1 to C10 alkyl group, a substituted or unsubstituted C6 to C20 aromatic hydrocarbon group, or a combination thereof.

6. The hardmask composition as claimed in claim 1, wherein in Chemical Formula 1,
Ar¹ and Ar² are each independently a substituted or unsubstituted group of a moiety of Group 1-2,
R¹ and R² are each independently hydrogen, deuterium, a substituted or unsubstituted C1 to C10 alkyl group, a substituted or unsubstituted C6 to C20 aromatic hydrocarbon group, or a combination thereof, and
n is an integer of 2 to 4:

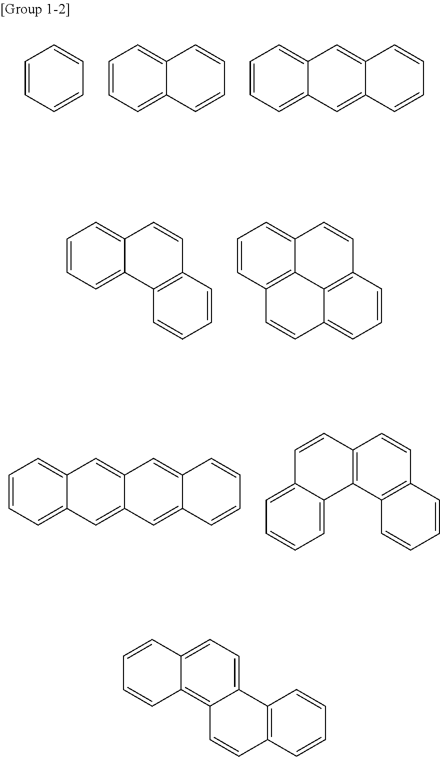

7. The hardmask composition as claimed in claim 1, wherein in Chemical Formula 1,
n is 2 or 3, and
each of R¹, R², and Ar² are the same.

8. The hardmask composition as claimed in claim 1, wherein:
the compound represented by Chemical Formula 1 is represented by one of Chemical Formula 2 to Chemical Formula 10:

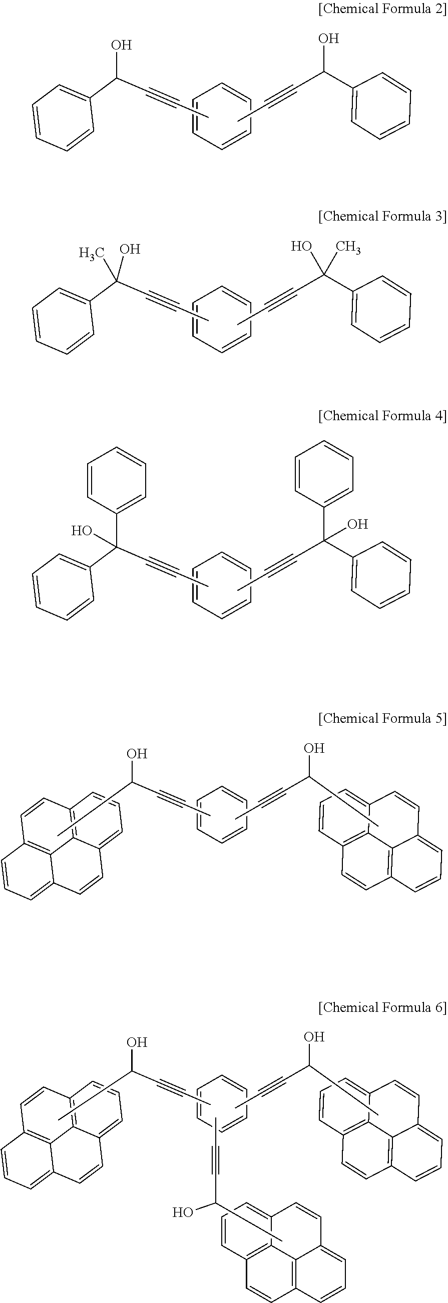

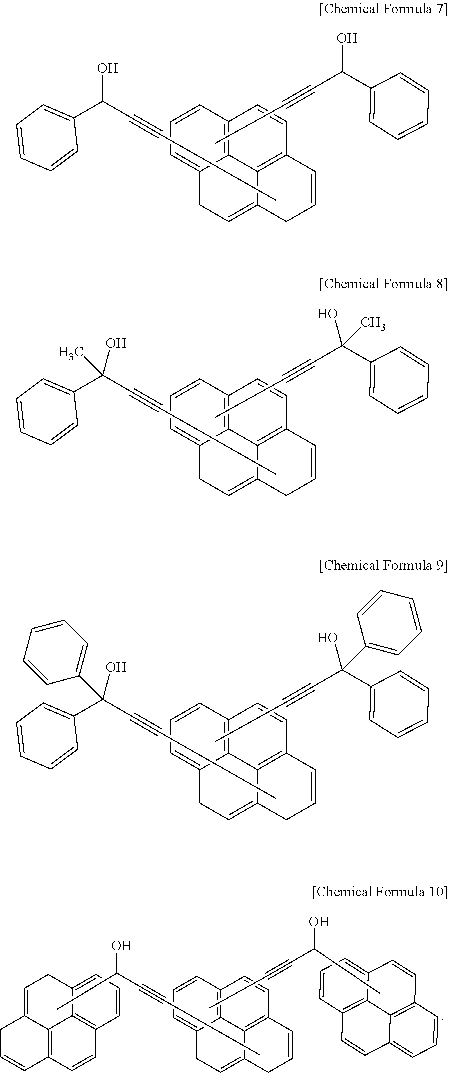

9. The hardmask composition as claimed in claim 1, wherein the compound has a molecular weight of about 300 g/mol to about 10,000 g/mol.

10. The hardmask composition as claimed in claim 1, wherein the compound is included in an amount of about 0.1 wt % to about 30 wt %, based on a total weight of the hardmask composition.

11. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyl lactate, gamma-butyrolactone, N,N-dimethyl formamide, N,N-dimethyl acetamide, methylpyrrolidone, methylpyrrolidinone, acetylacetone, or ethyl 3-ethoxypropionate.

12. A hardmask layer comprising a cured product of the hardmask composition as claimed in claim 1.

13. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

14. The method as claimed in claim 13, wherein forming the hardmask layer includes heat-treating at about 100° C. to about 1,000° C.
